(19) United States
(12) Patent Application Publication
(10) Pub. No.: US 2010/0029022 A1
(43) Pub. Date: Feb. 4, 2010

(54) METHOD FOR IMPROVED UTILIZATION OF SEMICONDUCTOR MATERIAL

(75) Inventors: Frank FEHRMANN, Priestewitz (DE); Juliane Busch, Dresden (DE); Volker Hansel, Dresden (DE); Daniel Ouellette, Danville, VT (US); Stojan Kanev, Thiendorf OT Sacka (DE)

Correspondence Address: HESLIN ROTHENBERG FARLEY & MESITI PC, 5 COLUMBIA CIRCLE, ALBANY, NY, 12203, US

(73) Assignee: SUSS MicroTec Test Systems GmbH, Sacka (DE)

(21) Appl. No.: 12/025,253

(22) Filed: Feb. 4, 2008

(30) Foreign Application Priority Data
Feb. 2, 2007 (DE) 10 2007 006 067.1

(51) Int. Cl. H01L 21/66; H01L 21/67

(52) U.S. Cl. 438/15; 29/25.01; 257/E21.521

(57) ABSTRACT

In a method for producing semiconductor components, in which chips are structured, tested, and isolated into dies on a wafer, in the event of a wafer being broken during the method, undamaged chips of a fragment of the wafer delimited by at least one edge section and at least one fracture contour are processed further as usual. The method has the result that the yield of usable chips is significantly increased in relation to the discarding and disposal of broken wafers provided in the prior art. The average production costs of electronic components and the loss of valuable semiconductor materials and the costs for the disposal of the fragments viewed as discards up to this point are thus significantly reduced.

The invention relates to a method for improved utilization of semiconductor material in the production of electronic components according to the preamble of claim 1 and a device for performing the method according to the preamble of claim 8.

To produce electronic components, integrated circuits, the so-called chips, are produced on a typically circular disk made of semiconductor material, the so-called wafer, subjected to various tests, and subsequently isolated into the so-called dies, which are finally sheeted into so-called packages. To perform all steps of the method which are to be performed in the production of the electronic components, the wafers and subsequently the dies must be transported back and forth between various devices and handled within the devices. It happens again and again that wafers break, which are then viewed as discards and are disposed of.

In particular in the processing of wafers made of especially high-value semiconductor materials, such as gallium arsenide, and in the processing of wafers on which an especially large number of chips are structured, for example, in the production of light emitting diodes (LED), the loss of a broken wafer causes a relatively large economic loss to the producer. The present invention therefore has the object of specifying a method for producing electronic semiconductor components, in which the semiconductor material of the wafer is utilized in an improved manner, and suggesting a device for performing the method.

The object is achieved according to the invention by a method having the features of claim 1 and a device having the features of claim 8. Advantageous embodiments and refinements of the invention are the subject matter of the dependent claims.

The method according to the invention for producing semiconductor components, in which chips are structured on a wafer, tested, and isolated into dies, is characterized in that in the event of a wafer broken during the method, the undamaged chips of a fragment of the wafer delimited by at least one edge section and at least one fracture contour are processed further as usual. The suggested method has the result that the yield of usable chips is significantly increased in relation to the discarding and disposal of broken wafers provided in the prior art. The average production costs of electronic components and the loss of valuable semiconductor materials and the costs for disposing of the fragments previously viewed as discards are thus reduced significantly.

In one embodiment of the invention, the fragment is positioned during the further processing in such a way that it has the same orientation as if it was still part of an undamaged wafer. In this way, a higher work effort in relation to the processing of undamaged wafers is avoided in that the fragment does not have to be handled in a different way than if it was still part of an undamaged wafer. Many method steps in the production of the electronic components are specifically oriented to how the chips are situated on the wafer. For example, the devices used for performing tests on the chips still located in the wafer composite are driven as a function of the configuration of the chips on the wafer, which is predefined by the wafer design. In a similar way, the devices which are used to isolate the chips into dies are driven as a function of the configuration of the chips on the wafer. For this purpose, a wafer coordinate system is defined for each wafer and the coordinates of every individual integrated circuit on the wafer within this wafer coordinate system are stored in the so-called wafer map. If the fragment, which possibly also contains chips usable further in addition to a number of damaged chips, is oriented as if it was still part of a complete wafer, the devices used for the various method steps may also be used for the further processing of the fragment without greater difficulties, i.e., the information about the position of a specific integrated circuit from the wafer map may also be used further unchanged in the further processing of the fragment.

To be able to perform the orientation of the fragment as much as possible without manual interventions, it is advisable for the position of the fragment within the wafer to be ascertained before its orientation. If the position of the fragment within the (undamaged) wafer is known, its positioning in the devices used for the method steps to be performed in relation to the tools provided for this purpose may be performed significantly more easily than would be possible, for example, with a “trial and error” method.

To ascertain the configuration information of the fragment required for the position of the fragment within the wafer, to be able to use the information from the wafer map about the positions of the individual integrated circuits in the wafer coordinate system during the further processing of the fragment, for example, the fragment may be scanned, at least one edge section and at least one characteristic structure being recognized. In general, in addition to the integrated circuits which are later isolated into dies and which are typically situated in rows and columns on the wafer, several characteristic structures are generally also typically applied to a wafer. These characteristic structures are frequently situated on the partition lines which run between the rows and columns of integrated circuits and which are also referred to as “dicing street” or “kerf,” or in the intersection point of two partition lines of this type. They are used, for example, for defining one or more localizable positions on the wafer, from which, starting as the origin of a coordinate system, individual chips may be approached and identified. The position of each chip in relation to at least one characteristic structure is noted in a so-called wafer map. To ascertain the position of the fragment within the wafer, a recognized edge section and at least one recognized characteristic structure may suffice. This is the case, for example, if every characteristic structure provided on the wafer is uniquely differentiable from every other characteristic structure. The scanning may be performed optoelectronically, for example. Optoelectronic scanning methods in the meaning of the described method are, for example, image acquisition using a camera and subsequent electronic image processing, laser triangulation, or methods using a reflection light barrier.

It is obvious that the characteristic structures do not necessarily have to be situated in the partition lines delimiting the integrated circuits, which are used for isolating the chips, or at intersection points of partition lines of this type. A characteristic structure in this meaning may, for example, also be provided within the matrix of integrated circuits instead of an integrated circuit. In the same way, a characteristic structure may be situated in the edge area of the wafer and thus outside the matrix configuration of integrated circuits. A characteristic structure may, however, also be an individual, uniquely differentiable special design of the edge contour of the wafer, for example, a notch or configuration of multiple notches, or the so-called flat, whose position in the coordinate system of the wafer is uniquely determinable, and therefore in combination with information about the curve of the edge contour and the fracture contour may provide sufficient information about the location and orientation of the particular fragment in the undamaged wafer and about the state of every integrated circuit contained on the fragment, i.e., whether the particular circuit is undamaged or damaged.

The recognition of the position of the fragment inside the wafer may be significantly simplified by taking orientation information from the characteristic structure. Of course, this presumes that at least one characteristic structure which contains orientation information is present on the wafer. Orientation information in this meaning indicates a detectable feature of a characteristic structure, on the basis of which the orientation of this characteristic structure in relation to the wafer and to the chips situated on the wafer may be uniquely established. An arrow is cited as an example, whose orientation is uniquely established by its direction (its course) and its direction meaning (the location of its tip).

In a refinement of the method, at least one fracture contour is recognized and the non-damaged chips are identified on the basis of the course of the fracture contour. For this purpose, for example, during the scanning of the fragment, every contour section which does not correspond to the edge contour of the wafer, determined by its curvature, inter alia, is identified as a fracture contour. Starting from the position of the fragment within the wafer ascertained in the way described above, the course of the fracture contour in relation to the undamaged wafer and thus in relation to the chips situated on the undamaged wafer and documented in the wafer map is known. Therefore, it may be uniquely established which chips situated on the original undamaged wafer lie on the fracture edge of the fragment and are damaged by the fracture contour. These chips may be marked as defective in the wafer map, so that processing time is saved in the following method steps in that these chips marked as defective are not processed further.

Furthermore, the position of a fragment within the wafer may be ascertained on the basis of the already ascertained position of another fragment. In this way, fragments which do not themselves contain a characteristic structure may also be used further. Of course, however, this embodiment of the method may also be applied for fragments which do contain their own characteristic structures, alternatively or additionally to the analysis of the information contained in their own characteristic structures.

The required information about the fragment adjoining the fragment already examined may be obtained, for example, in that the shared fracture contour of two adjoining fragments is brought into correspondence. Electronic image processing methods may be used for this purpose, for example.

The method may be simplified further in that in connection with the examination of a fragment, chips already recognized as damaged are not considered in the examination of an adjoining fragment. If a chip is already recognized as defective during the examination of the first fragment, only a part of this chip is typically located on the first fragment, while another part belongs to the adjoining fragment and therefore does not have to be examined once again in regard to its state.

The device described in the following is suggested to perform the method:

The device according to the invention for processing a fragment of a wafer delimited by at least one edge section and at least one fracture contour comprises a handling unit for handling the fragment, a scanning unit for obtaining configuration information of the fragment, a storage unit for storing configuration information of the wafer, and a comparison and control unit for comparing the configuration information of fragment and wafer and for controlling the handling unit during the positioning of the fragment.

The suggested device allows the automated performance of the method according to the invention, so that the yield may be significantly increased during the production of electronic components. This is true in particular, as already described above, for wafers made of very expensive semiconductor materials and wafers having very many chips situated thereon.

For example, the scanning unit may be an electronic camera which generates a digital image of the fragment. The storage unit and the comparison and control unit may be, for example, the hard drive and the processor of a computer, respectively, to which the electronic camera is connected. The configuration information of the wafer, for example, an image of an undamaged wafer and/or the wafer map, may be stored on the hard drive of the computer, to which the comparison and control unit has access. The determination of the position of the fragment within the wafer may, for example, be caused by image recognition methods known per se, in which the image of the fragment generated by the electronic camera is compared to the image of the undamaged wafer stored on the hard drive. The data required for the control of the handling unit may then be derived from the comparison of the actual position of the fragment to its intended position and transmitted to the handling unit, which then causes positioning of the fragment.

The described method is explained in greater detail in the following on the basis of drawings.

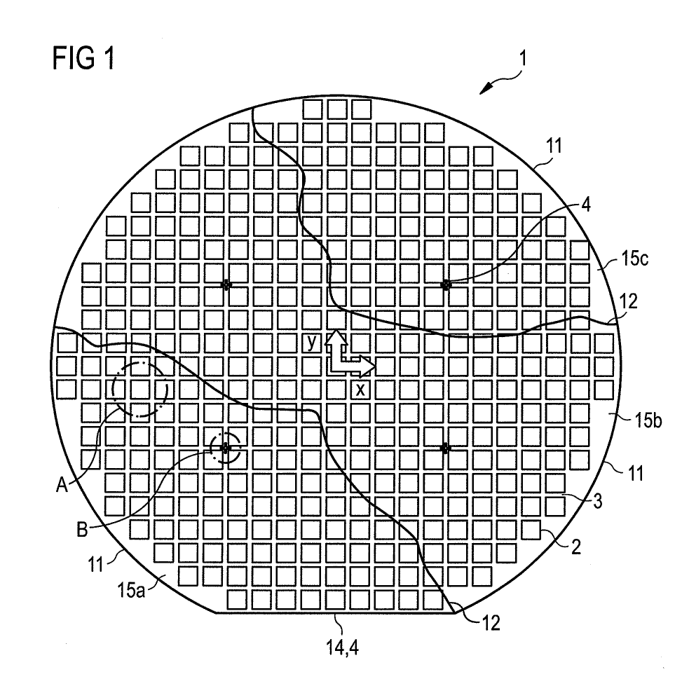

FIG. 1 shows an exemplary wafer having two fracture contours,

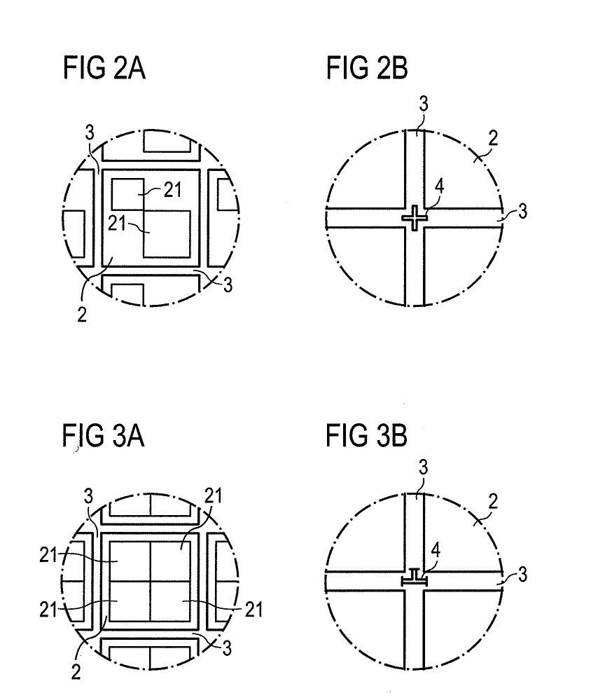

FIG. 2 shows two enlarged details of a first exemplary embodiment of the wafer from FIG. 1,

FIG. 3 shows two enlarged details of a second exemplary embodiment of the wafer from FIG. 1.

The wafer 1 in FIG. 1 comprises a large number of identical integrated circuits 2, which are situated in rows and columns. A horizontal partition line 3, also referred to as dicing street or kerf, is located between each two rows of integrated circuits 2. A vertical partition line 3 is located in the same way between each two columns of integrated circuits 2. The wafer 1 is sawed along these partition lines 3 at a later point in time to isolate the integrated circuits 2 contained thereon.

The so-called flat 14, a flattened area of the otherwise approximately circular wafer 1, which eases the orientation of the wafer 1 during the processing, is located at a specific point of the edge contour of the wafer 1, which is determined, inter alia, by the orientation of the crystal lattice of the wafer material. The angular orientation of the wafer is indicated with the aid of a primary and possibly a secondary flat 14. Alternatively, notches, i.e., notches situated at the edge of the wafer 1, which may fulfill the same function in regard to the positioning of the wafer 1, may also be used to determine the orientation of the wafer 1 instead of the flat(s) 14.

A coordinate system 13 is shown in the middle of the wafer 1, which is used for determining the position of each individual integrated circuit 2 on the wafer 1.

Furthermore, multiple characteristic structures 4 are situated on the wafer 1. In the exemplary embodiment, these are situated at each of the intersection points of a horizontal and a vertical partition line 3, i.e., outside the area of the wafer 1 occupied by the integrated circuits 2. The position of each individual one of these characteristic structures 4 may also be specified in relation to the coordinate system 13, so that the relative position of each individual circuit 2 to every characteristic structure 4 may be ascertained easily.

Two areas A and B are identified on the wafer 1, which comprise an integrated circuit 2 (area A) or an intersection point of two partition lines 3 (area B) having a characteristic structure 4 situated thereon.

Furthermore, two fracture contours 12, which divide the wafer 1 into a total of three fragments 15, may be seen on the wafer 1. Each of these fragments 15 comprises, in addition to the fracture contour 12, a section of the edge contour 11 of the wafer 1, a number of undamaged integrated circuits 2, damaged integrated circuits 2 close to the fracture contours 12, and at least one characteristic structure 4.

FIGS. 2 and 3 each show two enlarged illustrations of the areas A and B of a wafer 1, as schematically shown in FIG. 1. The area A contains a complete integrated circuit 2, which is delimited by horizontal and vertical partition lines 3, as well as parts of the adjoining circuits 2. The area B shows an even more greatly enlarged intersection point of two partition lines 3, which separate the adjoining integrated circuits 2 from one another, as well as the characteristic structure 4 situated therein.

An exemplary embodiment is illustrated in FIG. 2, in which the characteristic structure 4 shown in area B does not have any orientation information. This is a cross-shaped marking, whose position in the undamaged wafer 1 may be ascertained on the basis of its location in relation to the edge contour 11 and the fracture contour 12. However, it may not yet be derived in all cases with sufficient reliability, solely from the information in regard to the position of the characteristic structure 4, how the fragment 15 is to be positioned to be able to proceed further as if the fragment 15 was still part of an undamaged wafer 1.

However, in this exemplary embodiment, the integrated circuits 2 themselves have a structure from which corresponding orientation information may be inferred. As may be seen from the damaged integrated circuit 2 shown in the area A, every integrated circuit 2 has two substructures 21, which are different sizes and are situated in a specific way in relation to one another. The location and orientation of these substructures 21 are recognizable in the same way as the edge contour 11 and the fracture contour 12 of each fragment.

By combination of the information thus obtained in regard to the position of the characteristic structure 4 in the coordinate system 13 of the wafer 1 and in regard to the correct orientation of the integrated circuits 2, the fragment 15 may be oriented during the further processing in such a way as if it was still part of an undamaged wafer.

In the exemplary embodiment shown in FIG. 3, in contrast, the integrated circuits 2 shown in the area A have a symmetric division into four equally large substructures 21 each. As a result, no orientation information may be inferred from the integrated circuit 21 itself.

However, the required orientation information may be taken in this exemplary embodiment from the characteristic structure 4 shown in the area B. The characteristic structure 4, which is again situated in the intersection area of two partition lines 3, has the shape of an upside-down letter T. If this characteristic structure 4 is recognized and brought into relation to the edge contour 11 and to the fracture contour 12 of the fragment 15, its position in the coordinate system 13 of the wafer 1 is known. In addition, due to the asymmetrical shape of the characteristic structure 4, it may be inferred how the fragment 15 must be oriented to be able to proceed further as if it was still part of an undamaged wafer 1.

It is also to be noted that at least for the first fragment 15a located on the bottom left in FIG. 1, in whose edge contour 11 the flat 14 is located, even without the characteristic structures 4 situated in the partition lines 3, the position and orientation of the fragment 15a in the coordinate system 14 of the wafer 1 may be ascertained, because the flat 14 exists only a single time and, in addition, in a precisely defined and known position in the coordinate system of the wafer 1. Therefore, the flat 14 itself is a characteristic structure 4 in the meaning of the suggested method.

From the information thus obtained, the position and orientation of the central second fragment 15b may be ascertained in turn, because the first fragment 15a and the second fragment 15b share a fracture contour 12 and therefore the position and orientation of the second fragment 15b may be ascertained from the already known information on the first fragment 15a, in that the fracture contours 12 of both fragments 15a, 15b are brought into correspondence. For integrated circuits 2 which were already recognized as defective during the examination of the first fragment 15a, the repeated determination of the state of the part of this defective integrated circuit 2 located on the second fragment 15b is dispensed with, by which time is saved.

Subsequently, the required information about the third fragment 15c may be ascertained in an analogous way from the already known information on the position and orientation of the second fragment in the coordinate system 13 of the wafer 1. In other words: it is also possible through the suggested method to ascertain the position and orientation of a fragment 15 on the basis of the characteristic structure 4 situated on another fragment 15.

1. A method for producing semiconductor components, in which chips are structured on a wafer, tested, and isolated into dies, wherein, in the event of a wafer being broken during the method, undamaged chips of a fragment of the wafer delimited by at least one edge section and at least one fracture contour are processed further as usual.

2. The method according to claim 1, wherein the fragment is positioned during the further processing to have a same orientation as if the fragment was still part of an undamaged wafer.

3. The method according to claim 2, wherein before the fragment is positioned, position of the fragment inside the wafer is ascertained.

4. The method according to claim 3, further comprising scanning the fragment with at least one edge section and at least one characteristic structure being recognized.

5. The method according to claim 4, wherein the scanning is performed optoelectronically.

6. The method according to claim 4, wherein orientation information is taken from the characteristic structure.

7. The method according to claims 4, wherein at least one fracture contour is recognized and chips damaged by the fracture are identified on basis of a course of the fracture contour.

8. The method according to one of claim 3, wherein the position of a fragment within the wafer is ascertained on basis of an already ascertained position of another fragment.

9. The method according to claim 8, wherein a shared fracture contour of two adjoining fragments is brought into correspondence.

10. The method according to one of claim 7, wherein, in connection with examination of a fragment, chips already recognized as damaged are not considered during the examination of an adjoining fragment.

11. A device for processing a fragment of a wafers, delimited by at least one edge section and at least one fracture contour, comprising a handling unit for handling the fragment, a scanning unit for obtaining configuration information of the fragment, a storage unit for storing configuration information of the wafer, and a comparison and control unit for comparing the configuration information of the fragment and the configuration information of the wafer and for controlling the handling unit during the positioning of the fragment.
